(19) United States
(12) Patent Application Publication
(10) Pub. No.: US 2007/0254244 A1
(43) Pub. Date: Nov. 1, 2007

(54) Method of forming a resist structure

(75) Inventor: Ching-Yu Chang, I-Lan (TW)

Correspondence Address: TUNG & ASSOCIATES, 836 W. LONG LAKE RD, SUITE 120, BLOOMFIELD HILLS, MI, 48302, US

(73) Assignee: Taiwan Semiconductor Manufacturing Co.,

(21) Appl. No.: 11/416,264

(22) Filed: May 1, 2006

(51) Int. Cl. G03F 7/26

(52) U.S. Cl. 430/322; 430/330

(57) ABSTRACT

The present invention includes a method of forming a resist structure comprising depositing a first photoresist material over a first layer. Selectively exposing portions of the first layer to light to provide exposed portions and unexposed portions in the first photoresist layer. Without developing the first photoresist layer, depositing a second photoresist layer over the first photoresist layer including both exposed portions and unexposed portions. The second photoresist layer being capable of crosslinking in the presence of an acid. Treating the first photoresist layer to cause an acid from only one of the exposed portions or unexposed portions of the first photoresist layer producing a plurality of crosslinked portions of the second photoresist layer. Thereafter, developing the second photoresist layer to remove uncrosslinked portions.

### FIELD OF THE INVENTION

The present invention relates to a method of making a resist structure.

### BACKGROUND OF THE INVENTION

FIGS. 1A-E illustrate a known method of making a photoresist structure. A first layer 10 is provided and a first photoresist 12 is provided over the first layer 10. The first layer 10 may be a metallization layer, dielectric layer, or a semiconductor substrate, for example, a silicon wafer. The first photoresist layer 12 is exposed, developed and patterned to produce a plurality of first photoresist features 14. Each of the first photoresist features 14 has an upper surface 16 and at least a first sidewall 18, and typically a second opposite sidewall 20 as shown in FIG. 1B.

Thereafter, as shown in FIG. 1C, a second photoresist 22 is applied over the structure of FIG. 1B. The upper surface 16, the first sidewall 18 and the second sidewall 20, are all covered by the second photoresist material 22.

Thereafter, as shown in FIG. 1D, the structure of FIG. 1C is heated to release an acid in the plurality of individual photoresist features 14. The second photoresist material 22 may be crosslinked upon exposure to the acid released from the plurality of photoresist features 14. The acid diffuses from the upper surface 16, first sidewall 18 and second sidewall 20 outwardly into the second photoresist material 22. Thereafter, the uncrosslinked portions of the second photoresist layer 22 are removed by, for example, developing using a liquid chemical developer to dissolve the soluble regions of the photoresist. The above-described process may be utilized to produce photoresist structures having a relatively narrow gap 48 between structures caused by the crosslinked portion 24 of the first photoresist 12 that extends along each of the first sidewall 18 and the second sidewall 20 from the upper face 16 down to the first layer 10.

Sugino et al., U.S. Pat. No. 6,566,040, issued May 20, 2003, discloses a hole pattern or separation pattern of a first resist that is capable of supplying acid formed on a semiconductor substrate. A crosslinking film is formed on the sidewall of the first substrate pattern to obtain a resist pattern having a reduced hole diameter or separation width. Then, the hole diameter or the separation width is further reduced by causing thermal reflow of the crosslinked film. The semiconductor substrate is etched by using a resulting resist pattern as a mask. The water-soluble crosslinking agents used as the second resist include urea crosslinking agents such as urea, alkoxymethylene ureas, N-alkoxymethylene ureas, ethyleneurea, ethylene urea carboxylates and the like, melamine crosslinking agents such as melamine, alkoxymethylene melamines and the like, and amino crosslinking agents such as benzoguanamine, glycoluril and the like. Examples of water-soluble resist materials usable as the second resist include, aside from the water-soluble crosslinking agents used singly or in combination, the mixtures of these resins and crosslinking agents. The material for the first photoresist may be one which makes use of a mechanism capable of generating an acidic component inside the photoresist by an appropriate thermal treatment, and may be either a positive or negative photoresist. Examples of photoresist include novolac resin and a naphthoquinonediazide photosensitive agent. A chemically amplified resist making use of an acid generating mechanism may also be used as the first photoresist.

Ishibashi et al., U.S. Pat. No. 6,319,853, issued Nov. 20, 2001, discloses a method of producing a pure resist pattern having superior topography smaller than the limit of wavelength of exposure light. A first photoresist pattern containing material capable of producing an acid on exposure to light is coated with a second resist containing material which causes a crosslinking reaction in the presence of an acid. An acid is produced in the photoresist pattern by exposing the pattern to light, thus forming a crosslinked layer along the boundary surface between the first resist pattern and the second resist pattern. As a result, the second resist pattern which is greater than the first resist pattern is formed.

Tanaka et al., U.S. Pat. No. 6,593,063, issued Jul. 15, 2003, discloses a first resist layer capable of generating an acid formed on a semiconductor base and is developed in a shortened development time than usual. The first resist pattern is covered with a second resist layer containing a material capable of crosslinking in the presence of an acid. The acid is generated in the first resist pattern by application of heat or by exposure to light, and a crosslinked layer is formed in the second resist pattern at the interface with the first resist pattern as a cover layer for the first resist pattern, thereby the first resist pattern is caused to be thickened. The non-crosslinked portion of the second resist pattern is removed and the fine resist pattern is formed. The hole diameter of the resist pattern can be reduced, or the isolation width of a resist pattern may be produced utilizing this method.

Applicant's invention provides an alternative to the prior art.

### SUMMARY OF THE INVENTION

The present invention includes a method of forming a resist structure comprising depositing a first photoresist material over a first layer. Selectively exposing portions of the first layer to light to provide exposed portions and unexposed portions in the first photoresist layer. Without developing the first photoresist layer, depositing a second photoresist layer over the first photoresist layer including both exposed portions and unexposed portions. The second photoresist layer being capable of crosslinking in the presence of an acid. Treating the first photoresist layer to cause an acid from only one of the exposed portions or unexposed portions of the first photoresist layer producing a plurality of crosslinked portions of the second photoresist layer. Thereafter, developing the second photoresist layer to remove uncrosslinked portions.

Other embodiments of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1A illustrates a step in a prior art method of forming a photoresist structure including depositing a first photoresist layer on a first layer.

FIG. 1B illustrates a step in a prior art method including exposing, developing and patterning portions of the first photoresist layer.

FIG. 1C illustrates a step in a prior art method including depositing a second photoresist layer over the structure of FIG. 1B.

FIG. 1D illustrates a step in a prior art method including heating features formed by the first photoresist layer to cause an acid to be diffused from the features and crosslinked with the second photoresist layer along the boundary surfaces of the first photoresist features.

FIG. 1E illustrates a step in a prior art method including developing a second photoresist layer to remove uncrosslinked portions and to produce a photoresist structure having a relatively narrow gap between adjacent photoresist.

FIG. 2A illustrates a method according to one embodiment of the present invention including depositing a positive photoresist material over a first layer.

FIG. 2B illustrates a method according to one embodiment of the present invention including selectively exposing portions of the first layer to light thereby producing exposed portions and unexposed portions of the first layer.

FIG. 2C illustrates a method according to one embodiment of the present invention including depositing a second photoresist layer over the first photoresist layer including the exposed portions and unexposed portions.

FIG. 2D illustrates a method according to one embodiment of the present invention including causing an acid to be diffused from an upper surface of the unexposed portions of the first photoresist and producing crosslinked portions in the second photoresist aligned with the upper surface of the unexposed portions of the first photoresist.

FIG. 2E illustrates a method according to one embodiment of the present invention including developing the first and second photoresist layers to remove the non-crosslinked portions of the second photoresist layer and the exposed portions of the first photoresist layer.

FIG. 3A illustrates a method according to one embodiment of the present invention including providing a negative photoresist layer over a first layer.

FIG. 3B illustrates a method according to one embodiment of the present invention including exposing portions of the first photoresist layer to light to create exposed portions and unexposed portions in the first photoresist layer.

FIG. 3C illustrates a method according to one embodiment of the present invention including depositing a second photoresist layer over the first photoresist layer without developing the first photoresist layer so that the second photoresist layer covers both exposed portions and unexposed portions of the first photoresist layer.

FIG. 3D illustrates a method according to one embodiment of the present invention including causing an acid to diffuse from an upper surface of the exposed portions of the first photoresist layer and to crosslink portions of the second photoresist layer.

FIG. 3E illustrates a method according to one embodiment of the present invention including developing the first and second photoresist layers to remove non-crosslinked portions of the second photoresist layer and the unexposed portions of the first photoresist layer.

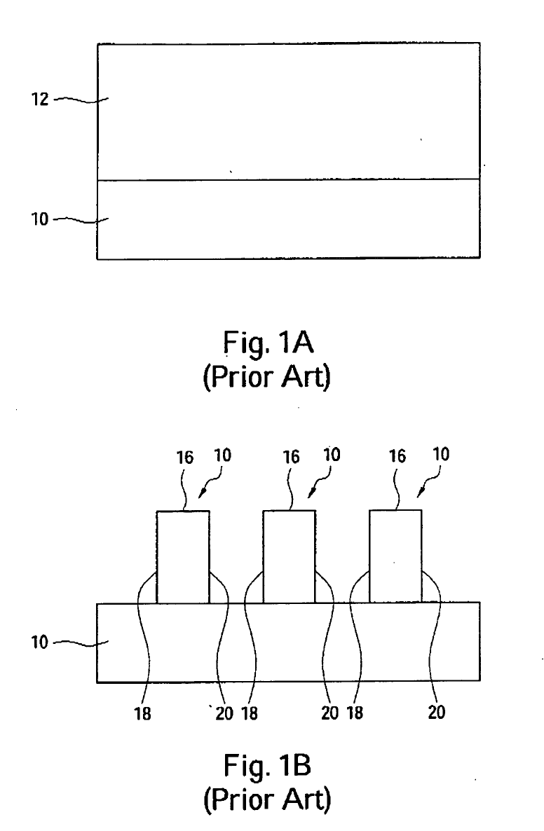

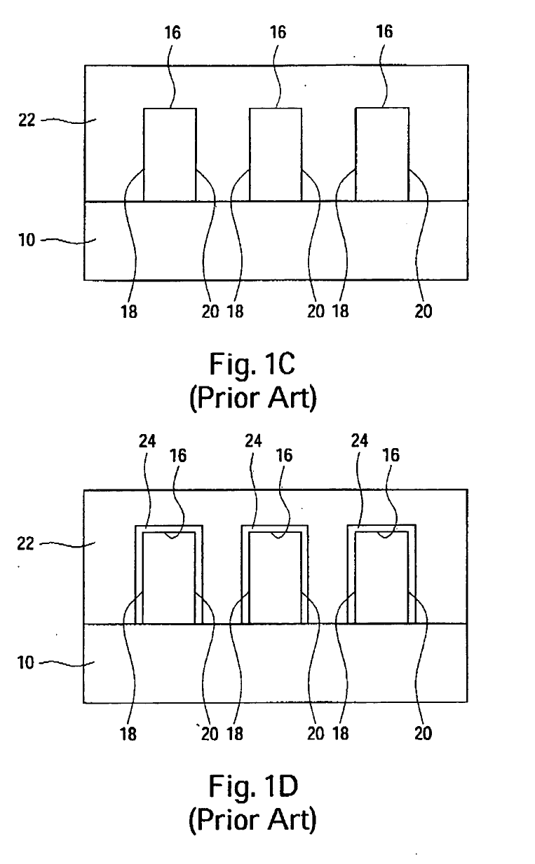

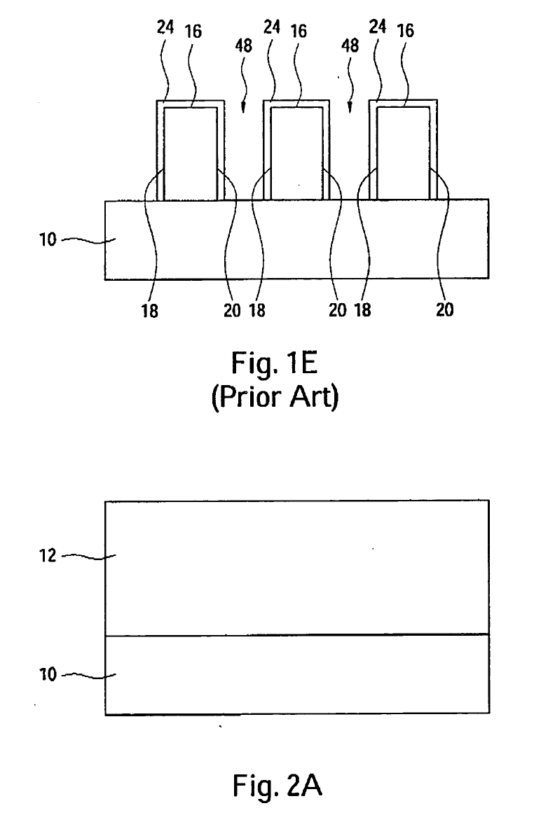

### DETAILED DESCRIPTION OF THE PREFERRED EMBODIMENTS

The following description of the preferred embodiment(s) is merely exemplary in nature and is in no way intended to limit the invention, its application, or uses.

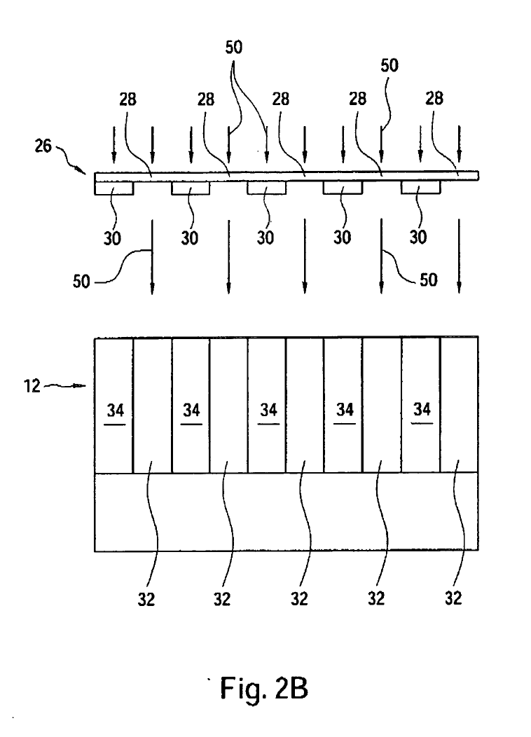

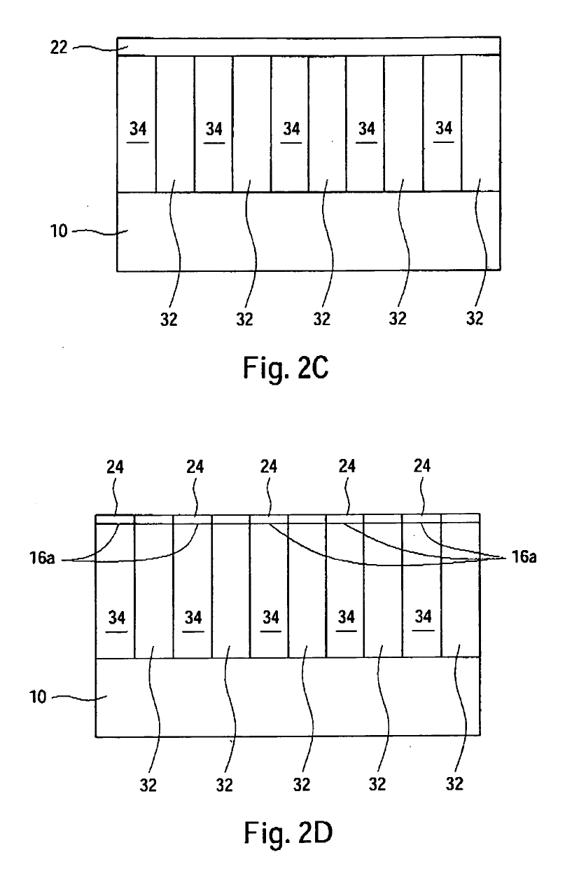

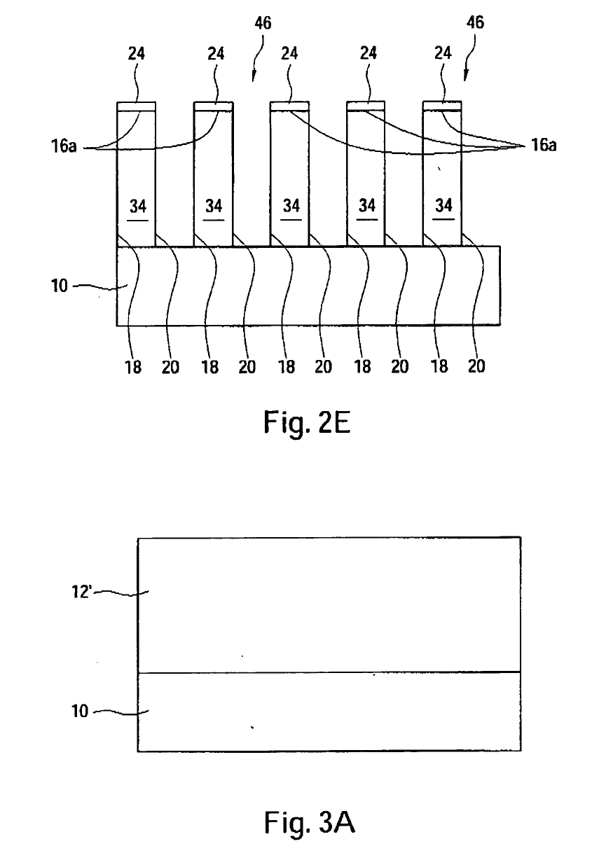

FIGS. 2A-E illustrate one embodiment of a method of making a photoresist structure according to the present invention. A first photoresist layer 12 may be deposited over a first layer 10. In one embodiment, the first photoresist layer 12 is a positive photoresist. A positive photoresist material is a crosslinked polymer before exposure to light. After the exposure process, the crosslinks of the exposed parts breakdown and become softened due to a photochemical reaction called photosolubilization, and will be dissolved by the developer while the unexposed parts remain on the first layer 10 or wafer surface. The first layer 10 may be a metallization layer, such as aluminum, copper and alloys thereof, a dielectric layer, for example, but not limited to, silicon dioxide, silicon, or silicon nitride.

As shown in FIG. 2B, a mask/reticle 26 which includes transparent portions 28 that allow light to travel therethrough, and non-transparent portions 30 which block light from traveling therethrough. Light 50 is shown through the mask 26 to create exposed portions 32 and unexposed portions 34 in the first photoresist layer 12.

Thereafter, without developing the first photoresist layer 12, a second photoresist layer 22 is deposited over the first photoresist layer 12 including both the exposed portions 32 and unexposed portions 34. The second photoresist layer 22 may be a positive photoresist. Thereafter, the first photoresist layer 12 is treated to cause an acid to diffuse from an upper surface 16a is located at the upper surface of the exposed portion 32 of the exposed portions 32. The second layer 22 is capable of photosolubilization upon exposure to an acid.

Thereafter, the first 12 and second 22 photoresist layers are developed to remove non-crosslinked portions of the second photoresist layer and the exposed portions 32 of the first photoresist layer 12 to provide a plurality of resist structures 46 including a first photoresist portion including an upper surface 16 and at least a first sidewall 18 and preferably a second sidewall 20 extending downwardly from the upper surface 16a to the first layer 10. The 16a photoresist structure 46 also includes a crosslinked portion 24 overlying the upper surface 16a of the first photoresist portion. The crosslinked portion 24 does not extend along the entire length of either of the sidewalls 18 or 20. In one embodiment, the crosslinked portion 24 does not extend the substantial length of either of the first sidewall 18 or the second sidewall 20. In one embodiment, the crosslinked portion 24 overlies the upper surface 16 of the first photoresist portion and does not extend a substantial distance along either of the first sidewall 18 or second sidewall 20.

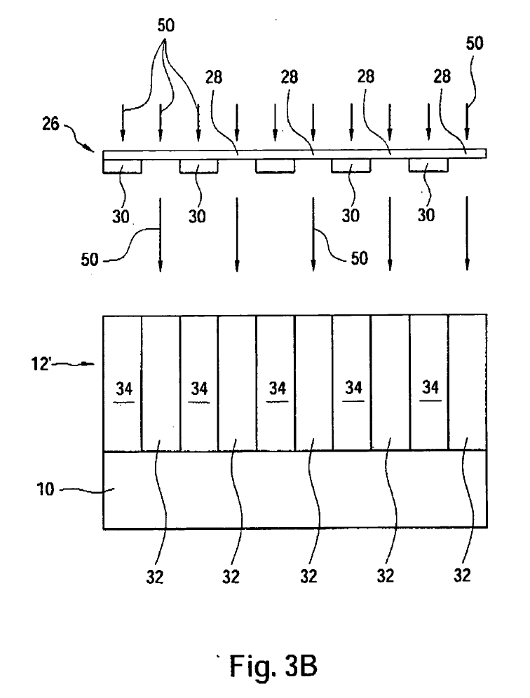

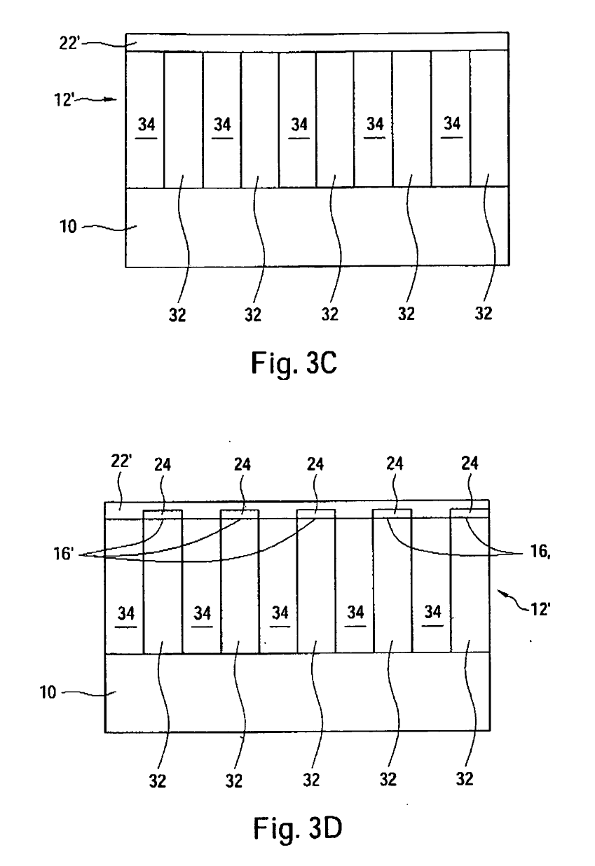

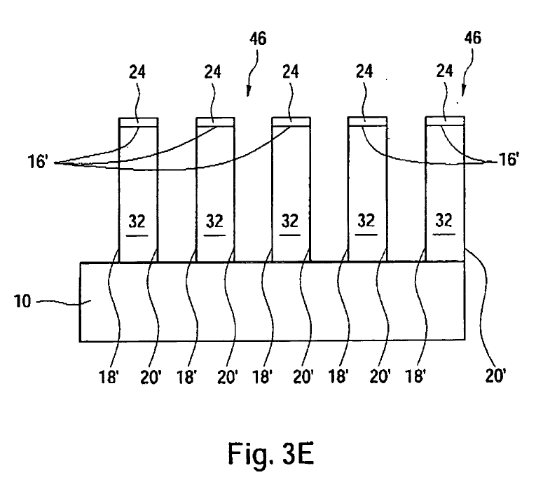

FIGS. 3A-E illustrate another embodiment of making a resist structure according to the present invention. The method illustrated in FIGS. 3A-E is similar to the method illustrated in FIGS. 2A-E, however, in the second embodiment, the first photoresist layer 12′ and the second photoresist layer 22′ are negative photoresist materials. Referring now to FIG. 3A, a first photoresist layer 12′, which is a negative photoresist material, is deposited over the first layer 10. Thereafter, as shown in FIG. 3B, a mask 26 including transparent portions 28 for transmitting light therethrough and non-transparent portions 30 for blocking light is used to selectively expose portions of the first photoresist layer 12′ producing exposed portions 32 and unexposed portions 34.

Thereafter, without developing the first photoresist layer 12′, a second photoresist layer 22′, which is a negative photoresist material, is deposited over the first photoresist layer 12′ including both exposed portions 32 and unexposed portions 34.

Thereafter, as illustrated in 3B, the exposed portions 32 of the first photoresist layer 12′ is treated to cause an acid to be diffused from an upper surface 16′ of the exposed portions 32.

Thereafter, the second photoresist layer 22′ and the first photoresist layer 12′ are developed to remove the uncrosslinked portions of the second photoresist layer 22′ and the unexposed portions 34 of the first photoresist layer 12′. A plurality of resist structures 46 are provided including the exposed portions 32 of the first photoresist layer 12′ which includes an upper surface 16′ at least a first sidewall 18′ and preferably a second sidewall 20′ each extending downwardly from the upper surface 16′ to the first layer 10. Crosslinked portions 24 of the second photoresist layer 22′ overlie the upper surface 16′ of the exposed portions 32 of the first photoresist layer 12′. The crosslinked portions 24 do not extend the entire length of either of the first sidewall 18′ or the second sidewall 20′. In one embodiment, the crosslinked portions 24 do not extend a substantial distance along either of the first sidewall 18′ or second sidewall 20′. Preferably, the crosslinked portions 24 overlie only the upper surface 16′ of the exposed portions 32.

In another embodiment of the invention, the second photoresist layer 22 or 22′ may include an anti-etch component, for example, but not limited to, Si, SiO₂, Ti and Ta.

In one embodiment, the first photoresist layer 12 is a positive photoresist and may include novolac resin and a naphthoquinonediazide photosensitive agent. The second photoresist 22 may include at least one of polyacrylic acid, polyvinyl acetal, polyvinylpyrrolidone, polyvinyl alcohol, polethyleneimine, polyethylene oxide, styrene-maleic acid copolymer, polyvinylamine resin, polyallylamine, oxazoline group-containing resins, water-soluble melamine resins, water-soluble urea resins, alkyl resins, sulfone amide resins, and the like.

The first photoresist layer 12 or 12′ may be coated by spin-coating, for example, but not limited to, onto a semiconductor substrate, followed by pre-baking, that is, a thermal treatment at 70-150° C. for around one minute to cause a solvent in the first photoresist to evaporate. The pattern in the first photoresist layer 12 or 12 may be formed by exposing the first photoresist layer to light through the mask 26, wherein the exposure light or beam may be a G-ray, an I-ray, deep UV light, KrF excimer laser beam, ArF excimer laser beam, an electron beam, an X-ray or the like which has a wavelength corresponding to the sensitizing wavelength of the first photoresist 12 or 12′. The first photoresist layer 12 or 12′ may also be a chemically amplified photoresist which make use of an acid generating mechanism. Other types of photoresist materials may also be used so far as they utilize reaction systems for generating acid upon exposure to heat or light. The second photoresist 22 or 22′ may be coated onto the semiconductor structure as well. The second photoresist 22 or 22′ primarily is composed of a crosslinkable material capable of crosslinkage in the presence of an acid, and capable of being dissolved in a solvent incapable of dissolving the first unexposed portions of the photoresist layer 12 or 12′. The second photoresist 22 or 22′ may also be coated by spray coating, spin coating or dipping in a second photoresist solution. After cooling the second photoresist 22 or 22′, the second photoresist may be pre-baked, for example, but not limited to, at 85° C. for about one minute. The first photoresist pattern and the second photoresist layer 22 or 22′ are thermally treated or mixing baked, at a baking temperature of 85-150° C. The treatment causes an acid to diffuse from the first photoresist pattern into the second photoresist layer 22′, and crosslinking reaction occurs at the interface between the second photoresist layer 22′ and the upper surface 16′ of the first photoresist feature. The treatment causes an acid to diffuse from the first photoresist pattern into the second photoresist layer 22, and photosolubilization reaction occurs at the interface between the second photoresist layer 22 and the upper surface 16′ of the first photoresist feature. The mixing bake step may proceed for approximately one to two minutes.

A liquid developer such as water or an alkaline aqueous solution of about 0.05 to 3 weight percent of terta methyl ammonium hydroxide may be used for development.

The second photoresist 22 or 22′ may be composed of a crosslinkable or photosolubilization water-soluble resin alone or a mixture of these resins. Alternatively, a water-soluble crosslinking agent alone or a mixture of these agents may also be used. Likewise, mixtures of these water-soluble resins and water-soluble crosslinking agents may be utilized.

Further, as the second resist, preferably used is a copolymer composed of two or more kinds of water soluble-resins as a main component, which is capable of generating or undergoing crosslinking or photosolubilization reaction in the presence of an acid.

Examples of the water soluble resins used as the second resist include, polyacrylic acid, polyvinyl acetal, polyvinylpyrrolidone, polyvinyl alcohol polethyleneimine, polyethylene oxide, styrene-maleic acid copolymer, polyvinylamine resin, polyallylamine, oxazoline group-containing resins, water-soluble melamine resins, water-soluble urea resins, alkyl resins, sulfone amide resins, and the like. The resins are not critical if they undergo crosslinking reaction in the presence of an acidic component. Alternatively, if they do not undergo crosslinking reaction, it is sufficient that the resins are miscible with a water-soluble crosslinking agent. These resins may be effectively used on their own or in combination.

These water soluble resins may be used singularly or in combination of two or more, and may be appropriately adjusted depending on and the reaction conditions and the reactivity with the underlying first resist 1. These water-soluble resins may be converted to salts, such as hydrochloride, for the purpose of improving the solubility in water.

The water-soluble crosslinking agents used as the second resist include, urea group crosslinking agents such as urea, alkoxymethylene ureas N-alkoxymethylene ureas, ethyleneurea, ethylene urea carboxylates and the like, melamine group crosslinking agents such as melamine, melamine derivative including alkoxymethylenemelamine, and amino crosslinking agents such as benzoguanamine, glycoluril and the like. Thus, the second resist may not be limited to amino crosslinking agents, and may include any of water-soluble crosslinking agents that generates crosslinking in the presence of acid.

Further, water-soluble resist materials used for the second resist may be a mixtures of these resins and the crosslinking agents. In these mixtures, the resins may be used singly or in combination, and the crosslinking agents may be used singly or in combination too.

For instance, preferably used is a mixture of a polyvinyl acetal resin as the water-soluble resin and ethyleneurea as the water-soluble crosslinking agent. In this case, because of the high solubility in water, the solution of the mixture exhibits good storage stability.

It will be noted that the material applied to as the second resist is not critical provided that it is soluble in water or soluble in a water-soluble solvent incapable of dissolving the first resist pattern and undergoes crosslinking reaction in the presence of an acidic component.

As set forth hereinbefore, the crosslinking reaction may proceed only by thermal treatment without generation of an acid by re-exposure of the first resist pattern 12, 12′. In this case, it is preferred that a material of high reactivity should be selected as the second resist 22 and that an appropriate thermal treatment, for example, at 85.degree C. to 150.degree C., should be effected.

As a specific example, preferably used as a second resist 22, 22′ is a water-soluble composition comprising polyvinyl acetal resin and ethyleneurea, or a composition comprising polyvinyl alcohol and ethyleneurea, or a mixture thereof at appropriate ratios.

The crosslinking reaction between the first resist 12, 12′ and the second resist 22, 22′ and the thickness of the crosslinked layer formed on the first resist pattern may be′ controlled as desired. The crosslinking reaction should be optimized depending on the reactivity between the first resist and the second resist, the shape of the first resist pattern, and the intended thickness of the crosslinked layer.

The effective process control of the crosslinking reaction may be done by the control of the MB (mixing bake) temperature and treating time. Especially, when the heating and crosslinking time (MB time) is controlled, the thickness of the crosslinked layer can be controlled. This method ensures a very good reaction control.

From the viewpoint of controlling the material composition used as the second resist 22, 22′, the control of the crosslinking reaction may be done by a technique wherein two or more of appropriate water-soluble resins are mixed at a controlled mixing ratio to control reactivity with the first resist, or a technique of mixing an appropriate water-soluble crosslinking agent with a water-soluble resin at a controlled mixing ratio to control reactivity with the first resist.

However, these controls of the crosslinking reaction should be determined while taking into account various conditions including (1) reactivity between the second resist material 22, 22′ and the first resist material 12, 12′, (2) the shape and thickness of the first resist pattern, (3) the intended thickness of the crosslinked layer, (4) usable exposure conditions or MB conditions, and (5) coating conditions.

In particular, it is known that the reactivity between the first resist 12, 12′ and the second resist 22, 22′ suffers an influence of the material composition of the first resist. In the practice of the present invention, the material composition of the second resist should preferably be optimized while taking the above-mentioned factors or conditions into consideration.

Accordingly, the types and compositional ratio of water-soluble material used as the second resist are not critical, and should be optimally determined depending on the types of materials and thermal treating conditions.

It will be noted that plasticizers, such as ethylene glycol, glycerine, triethylene glycol and the like, may be added to the second resist material as an additive.

It will also be noted that, in order to improve the film-forming properties, surface active agents, e.g. water-soluble surface active agents such as FLORADE (a fluorocarbon nonionic surfactant) of Sumitomo 3M Limited and NONIPOLE (a non-ionic polyoxyethylene nonylphenyl ether type surfactant) of Sanyo Chemical Industries Ltd., may be added to the second resist material as an additive.

The solvents used for the second resist 22, 22′ should not dissolve the first resist pattern and should well dissolve water-soluble materials. The solvents are not critical provided that the above requirements are satisfied.

The solvents mixed with water are not critical provided that they are soluble in water. Examples include alcohols such as ethanol, methanol, isopropyl alcohol and the like, gamma-butyrolactone, acetone, and the like. The solvent is mixed at a ratio in a range not dissolving the first resist pattern while taking into account the solubility of a material for the second resist.

In the present invention, the thus formed finely isolated resist pattern is used as a mask, followed by etching the underlying semiconductor substrate or the semiconductor base layer including various type of thin films to form fine spaces or holes in the semiconductor base layer. Thus, a semiconductor device can be manufactured.

In the present invention, a material and its composition for the second resist 22, 22′, and an MB temperature are appropriately determined, and the finely isolated resist pattern may be obtained by formation of the crosslinked layer on the first resist pattern. Then, a semiconductor substrate or semiconductor base layer may be etched by using such fine resist pattern as a mask. As a result, the side surfaces of the etched substrate can be effectively roughened.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method comprising:
depositing a first photoresist layer over a first layer;
selectively exposing portions of the first photoresist layer to light to create exposed portions and unexposed portions in the first photoresist layer;
without developing the first photoresist layer, depositing a second photoresist layer over the first photoresist layer including the exposed portions and unexposed portions, and wherein the second photoresist layer is capable of being crosslinked or photosolubilization upon exposure to an acid;
causing said acid to diffuse from only one of the exposed portions and of the first photoresist layer to the second photoresist layer
developing the second photoresist layer and the first photoresist layer to remove the developer soluble portions of the second photoresist layer leaving insoluble portions overlying an upper surface of only one of the exposed portions or unexposed portions of the first photoresist layer.

2. A method as set forth in claim 1 wherein the acid diffuses only from the exposed portion of the first photoresist.

3. A method as set forth in claim 1 wherein the first photoresist layer and the second photoresist layer comprise positive photoresist materials.

4. A method as set forth in claim 1 wherein the first photoresist layer and the second photoresist layer comprise a negative photoresist material.

5. A method as set forth in claim 1 wherein the second photoresist layer comprises an anti-etch component.

6. A method as set forth in claim 1 wherein the second photoresist layer further comprises at least one of Si, SiO₂, Ti and Ta.

7. A method as set forth in claim 1 wherein the crosslinked portions of the second layer only overlies an upper surface of one of the exposed portions or unexposed portions of the first photoresist layer.

8. A method as set forth in claim 1 wherein each of the exposed portions and unexposed portions of the first photoresist layer includes an upper face and at least a first sidewall, and wherein the crosslinked portion does not extend a substantial distance along the first sidewall.

9. A method as set forth in claim 1 wherein the treating comprises heating the first photoresist layer to a temperature ranging from 85-150° C to cause the acid to diffuse from one of the exposed portions or unexposed portions of the first photoresist layer.

10. A method as set forth in claim 1 wherein the first photoresist layer is chemically amplified.

11. A method as set forth in claim 1 wherein the second photoresist layer comprises a crosslinking agent comprising at least one of urea, alkoxymethylene ureas, N-alkoxymethylene ureas, ethyleneurea, ethylene urea carboxylates melamine, alkoxymethylene melamines, benzoguanamine, glycoluril.

12. A method as set forth in claim 1 wherein the second photoresist layer comprises at least one of polyacrylic acid, polyvinyl acetal, polyvinylpyrrolidone, polyvinyl alcohol polethyleneimine, polyethylene oxide, styrene-maleic acid copolymer, polyvinylamine resin, polyallylamine, oxazoline group-containing resins, water-soluble melamine resins, water-soluble urea resins, alkyl resins, sulfone amide resins.

13. A method comprising:
depositing a positive photoresist layer over a first layer;
selectively exposing portions of the first photoresist layer to light to create exposed portions and unexposed portions in the first photoresist layer, and wherein the exposed portions of the first photoresist layer are capable of generating an acid;
without developing the first photoresist layer, depositing a second positive photoresist layer over the first positive photoresist layer including the exposed portions and unexposed portions of the first photoresist layer;
heating the first photoresist layer to cause an acid to diffuse from the exposed portions of the first photoresist layer into the second photoresist layer and create insoluble portions in the second photoresist layer overlying the upper surface of the unexposed portions of the first layer;
developing the second positive photoresist layer to remove soluble portions and developing the first photoresist layer to remove exposed portions.

14. A method as set forth in claim 15 wherein the second photoresist layer comprises an anti-etching component.

15. A method as set forth in claim 15 wherein the second photoresist layer comprises at least one of Si, SiO₂, Ti and Ta.

16. A method as set forth in claim 15 wherein the insoluble portions of the second photoresist layer only overlie the upper surface of unexposed portions of the first photoresist layer.

17. A method as set forth in claim 15 wherein the insoluble portions of the second photoresist layer do not extend a substantial distance along a sidewall of the unexposed portions of the first photoresist layer.

18. A method comprising:
depositing a first negative photoresist layer over a first layer;
selectively exposing the first negative photoresist layer to light to create exposed portions and unexposed portions in the first negative photoresist layer;
without developing the first negative photoresist layer, depositing a second negative photoresist layer over the first negative photoresist layer including the exposed portions and unexposed portions;
heating the first negative photoresist layer to cause an acid to be generated from the exposed portions of the first negative photoresist layer and to crosslink with the second negative photoresist layer to create crosslinked portions overlying the exposed portions of the first photoresist layer;
developing the second negative photoresist layer to remove non-crosslinked portions and developing the first negative photoresist layer to remove the unexposed portions.

19. A method as set forth in claim 20 wherein the second negative photoresist layer further comprises an anti-etching component.

20. A method as set forth in claim 20 wherein the second negative photoresist layer comprises at least one of Si, SiO₂, Ti and Ta.

21. A method as set forth in claim 20 wherein the crosslinked portions only overlie an upper surface of the exposed portions of the first negative photoresist layer.

22. A method as set forth in claim 20 wherein the crosslinked portions do not extend a substantial distance along a sidewall of the exposed portions of the first negative photoresist layer.

23. A product comprising:
a first photoresist layer over a first layer, and wherein portions of the first photoresist layer having been exposed to light to create exposed portions and unexposed portions in the first photoresist layer, and wherein portion of the first photoresist layer having not been developed;
a second photoresist layer over the first photoresist layer including the exposed portions and unexposed portions, and wherein the second photoresist layer is capable of being insoluble upon exposure to an acid;
the second photoresist layer having insoluble portions therein overlying one of the exposed portions and unexposed portions of the first photoresist layer;
the second photoresist layer and the first photoresist layer having at least one opening therethrough and wherein insoluble portions of the second photoresist layer overly an upper surface of only one of the exposed portions and unexposed portions of the first photoresist layer.

24. A product as set forth in claim 25 wherein the insoluble portions of the second photoresist overly only from the exposed portions of the first photoresist.

25. A method as set forth in claim 25 wherein the insoluble portions of the second photoresist layer overly only from the unexposed portion of the first photoresist.

26. A product as set forth in claim 25 wherein the first photoresist layer and the second photoresist layer comprise positive photoresist materials.

27. A product as set forth in claim 25 wherein the first photoresist layer and the second photoresist layer comprise a negative photoresist material.

28. A product as set forth in claim 25 wherein the second photoresist layer comprises an anti-etch component.

29. A product as set forth in claim 25 wherein the second photoresist layer further comprises at least one of Si, SiO₂, Ti and Ta.

30. A product as set forth in claim 25 wherein the insoluble portions of the second layer only overlies an upper surface of one of the exposed portions or unexposed portions of the first photoresist layer.

31. A product as set forth in claim 25 wherein each of the exposed portions and unexposed portions of the first photoresist layer includes an upper face and at least a first sidewall, and wherein the insoluble portion does not extend a substantial distance along the first sidewall.

32. A product as set forth in claim 25 wherein the at least one of first photoresist layer and second photoresist layer comprises a novolac resin and a naphthoquinonediazide photoresist agent.

33. A product as set forth in claim 25 wherein the first photoresist layer is chemically amplified.

34. A product as set forth in claim 25 wherein the second photoresist layer comprises a crosslinking agent comprising at least one of urea, alkoxymethylene ureas, N-alkoxymethylene ureas, ethyleneurea, ethylene urea carboxylates melamine, alkoxymethylene melamines, benzoguanamine, glycoluril.

35. A product as set forth in claim 1 wherein the second photoresist layer comprises at least one of polyacrylic acid, polyvinyl acetal, polyvinylpyrrolidone, polyvinyl alcohol polethyleneimine, polyethylene oxide, styrene-maleic acid copolymer, polyvinylamine resin, polyallylamine, oxazoline group-containing resins, water-soluble melamine resins, water-soluble urea resins, alkyl resins, sulfone amide resins.

36. A product comprising:
a positive photoresist layer over a first layer;
wherein the first photoresist layer having portion having been exposed to light to create exposed portions and unexposed portions in the first photoresist layer, and wherein the unexposed portions of the first photoresist layer are capable of generating an acid;
wherein portions of the first photoresist layer have not been developed;
a second positive photoresist layer over the first positive photoresist layer including the exposed portions and unexposed portions of the first photoresist layer.

37. A product as set forth in claim 38 wherein the second photoresist layer comprises an anti-etching component.

38. A product as set forth in claim 38 wherein the second photoresist layer comprises at least one of Si, SiO₂, Ti and Ta.

39. A product as set forth in claim 38 wherein the crosslinked portions of the second photoresist layer only overlie the upper surface of unexposed portions of the first photoresist layer.

40. A product as set forth in claim 38 wherein the crosslinked portions of the second photoresist layer do not extend a substantial distance along a sidewall of the unexposed portions of the first photoresist layer.

41. A product comprising:
a first negative photoresist layer over a first layer;
the first negative photoresist layer having portions exposed to light to create exposed portions and unexposed portions in the first negative photoresist layer;
the first negative photoresist layer having portion not developed;
a second negative photoresist layer over the first negative photoresist layer including the exposed portions and unexposed portions;
the second negative photoresist layer having crosslinked portions overlying the exposed portions of the first photoresist layer;
the second negative photoresist layer and the first photoresist layer having at least one opening formed therethrough.

42. A product as set forth in claim 43 wherein the second negative photoresist layer further comprises an anti-etching component.

43. A product as set forth in claim 43 wherein the second negative photoresist layer comprises at least one of Si, SiO₂, Ti and Ta.

44. A product as set forth in claim 43 wherein the crosslinked portions only overlie an upper surface of the exposed portions of the first negative photoresist layer.

45. A product as set forth in claim 43 wherein the crosslinked portions do not extend a substantial distance along a sidewall of the exposed portions of the first negative photoresist layer.
